(19) United States
(12) Patent Application Publication
(10) Pub. No.: US 2025/0273469 A1
(43) Pub. Date: Aug. 28, 2025

(54) DEPOSITION APPARATUS AND DEPOSITION METHOD USING THE SAME

(71) Applicant: Samsung Display Co., LTD., Yongin-si (KR)

(72) Inventors: SOON-HWAN SO, Yongin-si (KR); EUISUK JUNG, Yongin-si (KR); TAE JOON KIM, Yongin-si (KR)

(73) Assignee: Samsung Display Co., LTD., Yongin-si (KR)

(21) Appl. No.: 19/011,756

(22) Filed: Jan. 7, 2025

(30) Foreign Application Priority Data
Feb. 28, 2024 (KR) 10-2024-0029277

(51) Int. Cl. H01L 21/288; C23C 14/04

(52) U.S. Cl. CPC H01L 21/2885; C23C 14/042

(57) ABSTRACT

A deposition device includes a deposition source which accommodates a deposition material, a mask including an electrode pattern to which a first voltage is applied, a stage to which a deposition target substrate is fixed, and a stage electrode pattern to which a second voltage is applied. A polarity of the first voltage and a polarity of the second voltage are same.

### CROSS REFERENCE TO RELATED APPLICATION(S)

This application claims priority to and benefits of Korean Patent Application No. 10-2024-0029277 under 35 U.S.C. § 119, filed on Feb. 28, 2024, in the Korean Intellectual Property Office (KIPO), the entire contents of which are incorporated herein by reference.

### BACKGROUND

### 1. Technical Field

Embodiments relate generally to a deposition apparatus and a deposition method using the deposition apparatus.

### 2. Description of Related Art

Augmented reality refers to a technology that displays a single image by overlapping a virtual image on the real image seen by the user's eyes. A virtual image can be an image in text or graphic form, and a real image can be information about a real object observed in the device's field of view.

Augmented reality can be implemented using a head mounted display (HMD), a head-up display (HUD), etc. When augmented reality is implemented using a head-mounted display, the glasses can be provided in the form of glasses so that the user can readily carry them and readily put them on or take them off. In this case, a display device that provides a virtual image to implement augmented reality is implemented using a micro display such as OLEDOS (Organic Light Emitting Diode on Silicon) or LCOS (Liquid Crystal on Silicon).

### SUMMARY

Embodiments provide a deposition apparatus.

Embodiments provide a deposition method using the deposition apparatus.

A deposition apparatus according to an embodiment may include a deposition source which accommodates a deposition material, a mask through which the deposition material passes, disposed on the deposition source, and including a first upper electrode pattern to which a first voltage is applied, a stage disposed on the mask and on which a deposition target substrate on which the deposition material is deposited is fixed, and a stage electrode pattern disposed on the mask and to which a second voltage is applied. A polarity of the first voltage and a polarity of the second voltage may be same.

In an embodiment, a repulsive force may occur between the stage electrode pattern and the first upper electrode pattern.

In an embodiment, the mask may further include a second upper electrode pattern to which a third voltage is applied. A polarity of the third voltage and the polarity of the first voltage may be same, a magnitude and the third voltage and a magnitude of the first voltage may be different from each other, and the second upper electrode pattern and the first upper electrode pattern may be spaced apart from each other.

In an embodiment, the mask may further include a second upper electrode pattern to which a third voltage is applied. A polarity of the third voltage and the polarity of the first voltage may be different from each other.

In an embodiment, the first upper electrode pattern may be disposed adjacent to a circumference of the mask, and the second upper electrode pattern may be disposed at a center of the mask.

In an embodiment, the mask may further include a lower electrode pattern to which a third voltage is applied. A polarity of the third voltage and the polarity of the first voltage may be different from each other.

In an embodiment, the deposition apparatus may further include a deposition source electrode pattern disposed on the deposition source and to which a fourth voltage is applied. The polarity of the third voltage and a polarity of the fourth voltage may be same.

In an embodiment, the first upper electrode pattern may be disposed adjacent to a circumference of the mask, and the lower electrode pattern may be disposed at a center of the mask.

In an embodiment, deposition areas in which a plurality of openings are formed may be defined in the mask, and the first upper electrode pattern may be disposed between the deposition areas.

In an embodiment, the mask may include silicon.

A deposition apparatus according to an embodiment may include a deposition source which accommodates a deposition material, a mask through which the deposition material passes, disposed on the deposition source, and doped inside with an electrode material to which a first voltage is applied, a stage disposed on the mask and on which a deposition target substrate on which the deposition material is deposited is fixed, and a stage electrode pattern disposed on the mask and to which a second voltage is applied.

In an embodiment, a polarity of the first voltage and a polarity of the second voltage may be same.

In an embodiment, a polarity of the first voltage and a polarity of the second voltage may be different from each other.

In an embodiment, a doping amount of the electrode material at a circumference of the mask and a doping amount of the electrode material doped at a center of the mask may be substantially same.

In an embodiment, a doping amount of the electrode material at a circumference of the mask may be smaller than a doping amount of the electrode material doped at a center of the mask.

A deposition method according to an embodiment may include applying a first voltage to an upper electrode pattern included in a mask, while the mask is being loaded, applying a second voltage to a stage electrode pattern disposed on the mask, while the mask is being loaded, applying a third voltage to a lower electrode pattern included in the mask, while a deposition process is in progress, applying a fourth voltage to a deposition source electrode pattern disposed under the mask, while the deposition process is in progress, applying a fifth voltage to the upper electrode pattern, while the mask is being unloaded, and applying a sixth voltage to the stage electrode pattern, while the mask is being unloaded. A polarity of the first voltage and a polarity of the second voltage may be same.

In an embodiment, a polarity of the third voltage and a polarity of the fourth voltage may be same.

In an embodiment, a polarity of the fifth voltage and a polarity of the sixth voltage may be same.

In an embodiment, a polarity of the first voltage and a polarity of the third voltage may be different from each other, and a polarity of the fifth voltage and the polarity of the third voltage may be different from each other.

Therefore, a deposition apparatus according to embodiments of the disclosure may include a deposition source, a mask, and a stage. An upper electrode pattern (or lower electrode pattern) may be formed on the mask, and a stage electrode pattern (or deposition source electrode pattern) may be formed on the stage (or the deposition source). A voltage having the same polarity may be applied to the upper electrode pattern and the stage electrode pattern. Accordingly, a repulsive force may occur between the upper electrode pattern and the stage electrode pattern. Accordingly, the gap between the mask and the deposition source (or the stage) may be adjusted, and the mask may not sag downward.

### BRIEF DESCRIPTION OF THE DRAWINGS

The accompanying drawings, which are included to provide a further understanding of the disclosure and are incorporated in and constitute a part of this specification, illustrate embodiments of the disclosure together with the description.

FIG. 1 is a schematic diagram illustrating a deposition apparatus according to an embodiment of the disclosure.

FIG. 2 is a plan view illustrating a mask included in the deposition apparatus of FIG. 1.

FIG. 3 is a rear view illustrating the mask of FIG. 2.

FIGS. 4, 5, and 6 are schematic diagrams illustrating a deposition method using the deposition apparatus of FIG. 1.

FIG. 7 is a plan view illustrating a mask included in a deposition apparatus according to an embodiment of the disclosure.

FIG. 8 is a rear view illustrating the mask of FIG. 7.

FIG. 9 is a schematic diagram illustrating the deposition apparatus of FIG. 7.

FIG. 10 is a plan view illustrating a mask included in a deposition apparatus according to an embodiment of the disclosure.

FIG. 11 is a rear view illustrating the mask of FIG. 10.

FIGS. 12, 13, and 14 are schematic diagrams illustrating a deposition method using the deposition apparatus of FIG. 10.

FIG. 15 is a plan view illustrating a mask included in a deposition apparatus according to an embodiment of the disclosure.

FIGS. 16, 17, and 18 are schematic diagrams illustrating a deposition method using the deposition apparatus of FIG. 15.

FIG. 19 is a plan view illustrating a mask included in a deposition apparatus according to an embodiment of the disclosure.

FIGS. 20, 21, and 22 are schematic diagrams illustrating a deposition method using the deposition apparatus of FIG. 19.

FIGS. 23 and 24 are perspective views illustrating an electronic device according to an embodiment of the disclosure.

### DETAILED DESCRIPTION OF THE EMBODIMENTS

Illustrative, non-limiting embodiments will be more clearly understood from the following detailed description in conjunction with the accompanying drawings.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

In the specification and the claims, the phrase “at least one of” is intended to include the meaning of “at least one selected from the group of” for the purpose of its meaning and interpretation. For example, “at least one of A and B” may be understood to mean “A, B, or A and B.” In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

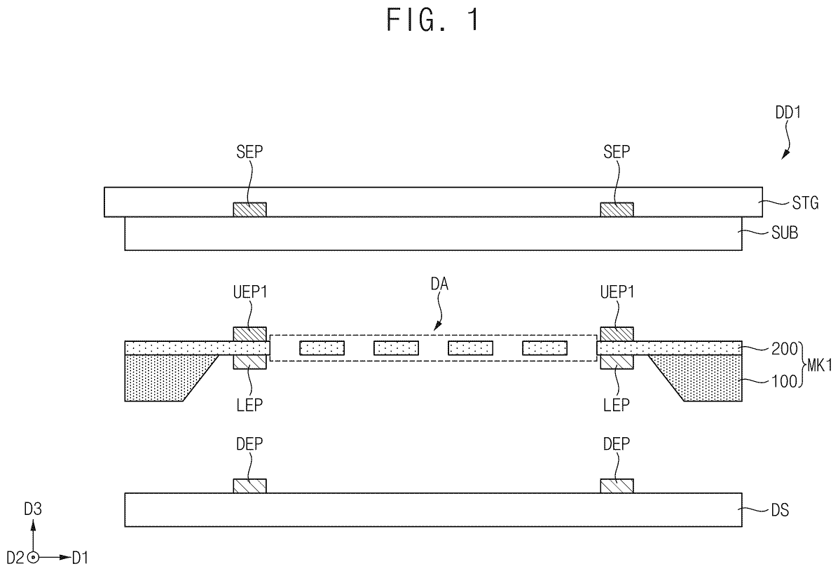

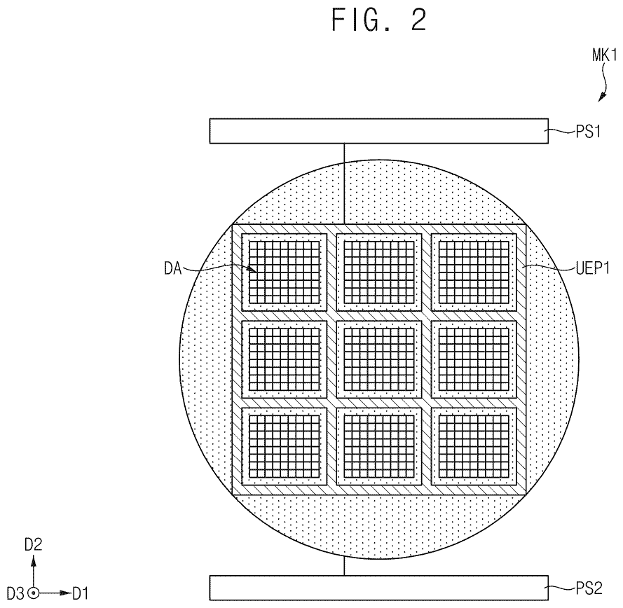

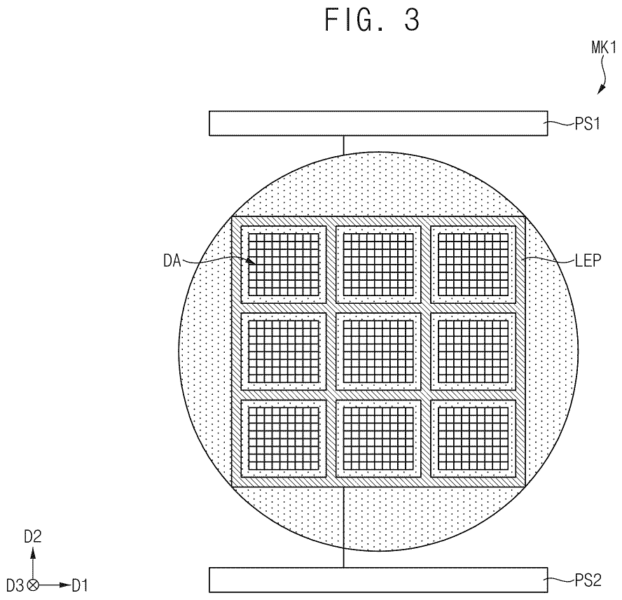

FIG. 1 is a schematic diagram illustrating a deposition apparatus according to an embodiment of the disclosure. FIG. 2 is a plan view illustrating a mask included in the deposition apparatus of FIG. 1. FIG. 3 is a rear view illustrating the mask of FIG. 2.

Referring to FIG. 1, a deposition apparatus DD1 according to an embodiment of the disclosure may include a deposition source DS, a deposition source electrode pattern DEP, a mask MK1, a stage STG, and a stage electrode pattern SEP. The mask MK1 may include a support member 100, a pattern member 200, a first upper electrode pattern UEP1, and a lower electrode pattern LEP. The deposition apparatus DD1 may deposit a deposition material on a deposition target substrate SUB.

The deposition source DS may accommodate a deposition material. For example, the deposition source DS may vaporize the deposition material, and the vaporized deposition material may flow to the deposition target substrate SUB through the mask MK1. In an embodiment, the deposition source DS may be disposed under the mask MK1 and may be disposed to face the deposition target substrate SUB with the mask MK1 interposed between the deposition source DS and the deposition target substrate SUB.

The deposition source electrode pattern DEP may be disposed on the deposition source DS. In an embodiment, the deposition source electrode pattern DEP may be movable on top of the deposition source DS. In another embodiment, the deposition source electrode pattern DEP may be fixed on top of the deposition source DS. In another embodiment, the deposition source electrode pattern DEP may be built into the deposition source DS.

In an embodiment, the deposition source electrode pattern DEP may be formed of an electrically conductive conductor. For example, the deposition source electrode pattern DEP may be formed of a metal material. Accordingly, in case that a voltage is applied to the deposition source electrode pattern DEP, the deposition source electrode pattern DEP may have a polarity.

In another embodiment, the deposition source electrode pattern DEP may be formed of a magnetic material that conducts magnetism.

The mask MK1 may be placed on the deposition source DS. For example, the mask MK1 may be disposed between the deposition source DS and the deposition target substrate SUB. The deposition material may pass through the mask MK1 through a pattern formed on the mask MK1.

In an embodiment, the support member 100 may be a wafer containing silicon. For example, the support member 100 may include at least one of a silicon wafer (Si wafer), a silicon carbide wafer (SiC wafer), and a silicon single crystal wafer (Si-single crystal wafer).

In an embodiment, the pattern member 200 may be disposed on the support member 100. For example, the pattern member 200 may be deposited on surfaces of the support member 100. The pattern member 200 may be formed of at least one of silicon (Si), silicon nitride (SiN), silicon oxide (SiO), etc.

In an embodiment, a deposition area DA in which multiple openings are formed may be defined in the pattern member 200. For example, a membrane for deposition may be formed on the pattern member 200, and the mask MK1 may function as a fine metal mask (FMM).

The mask MK1 may include the first upper electrode pattern UEP1. In an embodiment, the first upper electrode pattern UEP1 may be disposed on the pattern member 200 (or the support member 100). In another embodiment, the first upper electrode pattern UEP1 may be mounted inside the pattern member 200 (or the support member 100).

In an embodiment, the first upper electrode pattern UEP1 may be formed of an electrically conductive conductor. For example, the first upper electrode pattern UEP1 may be formed of a metal material. Accordingly, in case that a voltage is applied to the first upper electrode pattern UEP1, the first upper electrode pattern UEP1 may have a polarity.

In another embodiment, the first upper electrode pattern UEP1 may be formed of a magnetic material that conducts magnetism.

The mask MK1 may include the lower electrode pattern LEP. In an embodiment, the lower electrode pattern LEP may be disposed under the pattern member 200 (or the support member 100). In another embodiment, the lower electrode pattern LEP may be mounted inside the pattern member 200 (or the support member 100).

In an embodiment, the lower electrode pattern LEP may be formed of an electrically conductive conductor. For example, the lower electrode pattern LEP may be formed of a metal material. Accordingly, in case that a voltage is applied to the lower electrode pattern LEP, the lower electrode pattern LEP may have a polarity.

In another embodiment, the lower electrode pattern LEP may be formed of a magnetic material that conducts magnetism.

The stage STG may be disposed on the mask MK1, and the deposition target substrate SUB may be fixed to the stage STG.

The stage electrode pattern SEP may be disposed on the mask MK1. In an embodiment, the stage electrode pattern SEP may be mounted inside the stage STG. In another embodiment, the stage electrode pattern SEP may be disposed under the stage STG.

In an embodiment, the stage electrode pattern SEP may be formed of an electrically conductive conductor. For example, the stage electrode pattern SEP may be formed of a metal material. Accordingly, in case that a voltage is applied to the stage electrode pattern SEP, the stage electrode pattern SEP may have a polarity.

In another embodiment, the stage electrode pattern SEP may be formed of a magnetic material that conducts magnetism.

The deposition target substrate SUB may be disposed under the stage STG and may be fixed to the stage STG. The deposition target substrate SUB may be a substrate for manufacturing a display device and may be a glass substrate, a plastic substrate, a silicon substrate, or the like. For example, the deposition target substrate SUB may include at least one of a silicon wafer (Si wafer), a silicon carbide wafer (SiC wafer), and a silicon single crystal wafer (Si-single crystal wafer).

Referring to FIG. 2, the first upper electrode pattern UEP1 may be disposed on the mask MK1.

In an embodiment, multiple deposition areas DA may be defined in the mask MK1. For example, as shown in FIG. 2, nine deposition areas DA may be arranged in a matrix shape on the mask MK1.

The first upper electrode pattern UEP1 may be disposed between the deposition areas DA. For example, as shown in FIG. 2, the first upper electrode pattern UEP1 may be formed in a net shape in a plan view.

In an embodiment, the first upper electrode pattern UEP1 may be electrically connected to a first power source PS1. The first power source PS1 may apply a voltage to the first upper electrode pattern UEP1.

Referring to FIG. 3, the lower electrode pattern LEP may be disposed under the mask MK1.

In an embodiment, multiple deposition areas DA may be defined in the mask MK1. For example, as shown in FIG. 2, nine deposition areas DA may be arranged in a matrix shape on the mask MK1.

The lower electrode pattern LEP may be disposed between the deposition areas DA. For example, as shown in FIG. 2, the lower electrode pattern LEP may be formed in a net shape in a plan view.

In an embodiment, the lower electrode pattern LEP may overlap the first upper electrode pattern UEP1 in a plan view.

In an embodiment, the lower electrode pattern LEP may be electrically connected to a second power source PS2. The second power source PS2 may apply a voltage to the lower electrode pattern LEP.

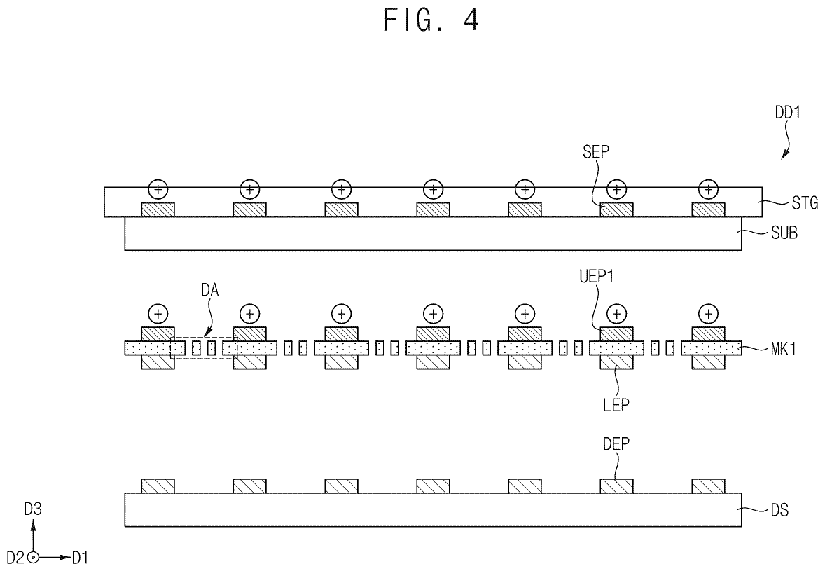

FIGS. 4, 5, and 6 are schematic diagrams illustrating a deposition method using the deposition apparatus of FIG. 1.

Referring to FIG. 4, the deposition target substrate SUB may be fixed to the stage STG, and the mask MK1 may be loaded.

While the mask MK1 is being loaded, a voltage may be applied to the first upper electrode pattern UEP1 included in the mask MK1. For example, a voltage having a positive polarity (+) may be applied to the first upper electrode pattern UEP1.

While the mask MK1 is loaded, a voltage may be applied to the stage electrode pattern SEP. For example, while a voltage with a positive polarity (+) is applied to the first upper electrode pattern UEP1, a voltage with a positive polarity (+) may be applied to the stage electrode pattern SEP.

As a voltage having a same positive polarity (+) is applied to the first upper electrode pattern UEP1 and the stage electrode pattern SEP, a repulsive force may occur between the first upper electrode pattern UEP1 and the stage electrode pattern SEP. Accordingly, collision between the deposition target substrate SUB and the mask MK1 may be prevented.

As the magnitude of the voltage applied to the first upper electrode pattern UEP1 and the stage electrode pattern SEP are adjusted, the gap between the mask MK1 and the deposition target substrate SUB may be adjusted.

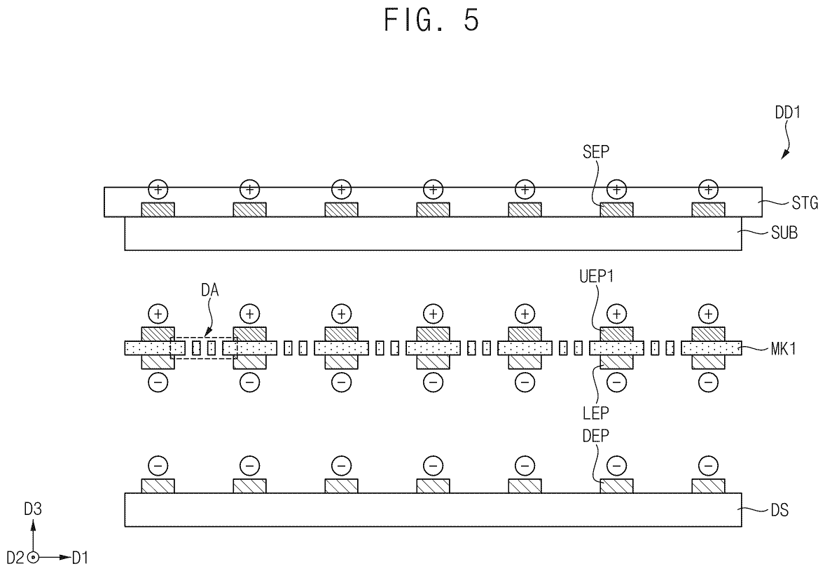

Referring to FIG. 5, the deposition process may be proceeded.

While the deposition process is in progress, a voltage may be applied to the lower electrode pattern LEP included in the mask MK1. For example, a voltage having a negative polarity (−) may be applied to the lower electrode pattern LEP. In other words, the polarity of the voltage applied to the first upper electrode pattern UEP1 and the polarity of the voltage applied to the lower electrode pattern LEP may be different from each other.

While the deposition process is in progress, a voltage may be applied to the deposition source electrode pattern DEP. For example, while a voltage with a negative polarity (−) is applied to the lower electrode pattern LEP, a voltage with a negative polarity (−) may be applied to the deposition source electrode pattern DEP.

As a voltage having a same negative polarity (−) is applied to the lower electrode pattern LEP and the deposition source electrode pattern DEP, the repulsive force may occur between the lower electrode pattern LEP and the deposition source electrode pattern DEP. Accordingly, the mask MK1 may not sag downward.

As the magnitude of the voltage applied to the lower electrode pattern LEP and the deposition source electrode pattern DEP are adjusted, the gap between the mask MK1 and the deposition source DS may be adjusted.

While the deposition process is in progress, a voltage having a same positive polarity (+) may be applied to the first upper electrode pattern UEP1 and the stage electrode pattern SEP.

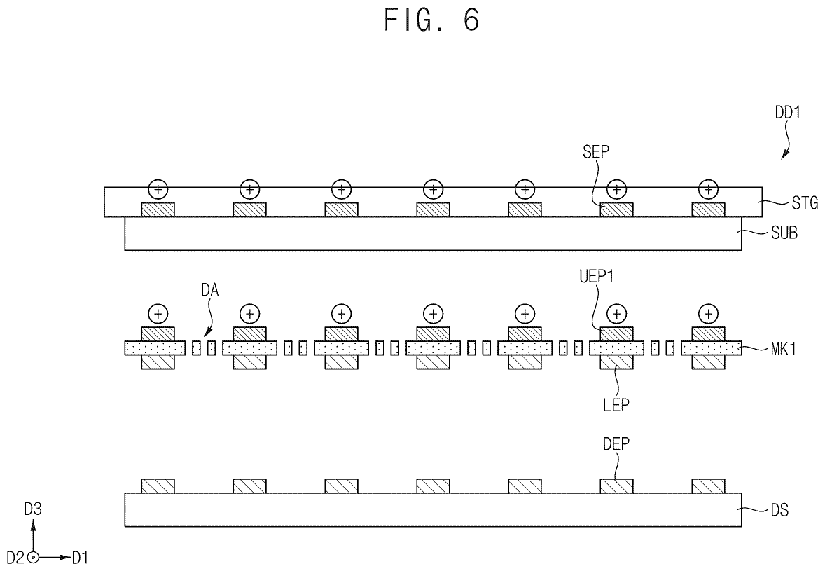

Referring to FIG. 6, the mask MK1 may be unloaded.

While the mask MK1 is unloaded, a voltage having a positive polarity (+) may be applied to the first upper electrode pattern UEP1. While a voltage with a positive polarity (+) is applied to the first upper electrode pattern UEP1, a voltage with a positive polarity (+) may be applied to the stage electrode pattern SEP.

As a voltage having a same positive polarity (+) is applied to the first upper electrode pattern UEP1 and the stage electrode pattern SEP, a repulsive force may occur between the first upper electrode pattern UEP1 and the stage electrode pattern SEP. Accordingly, collision between the deposition target substrate SUB and the mask MK1 may be prevented.

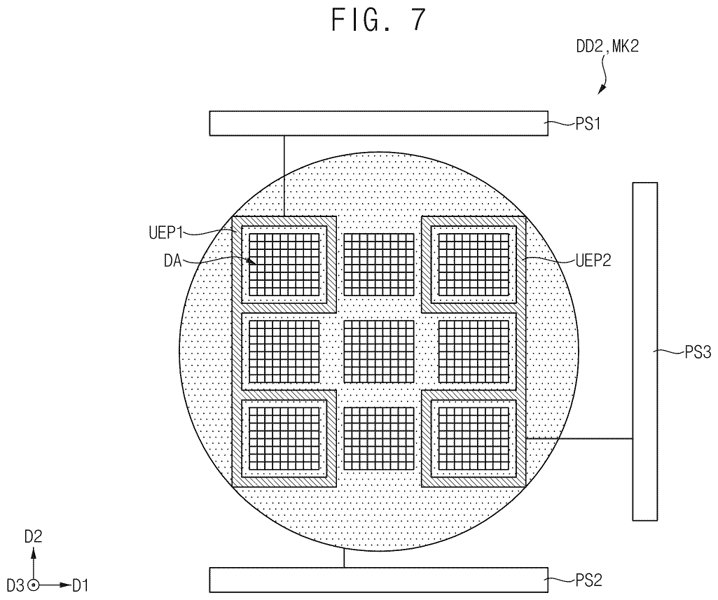

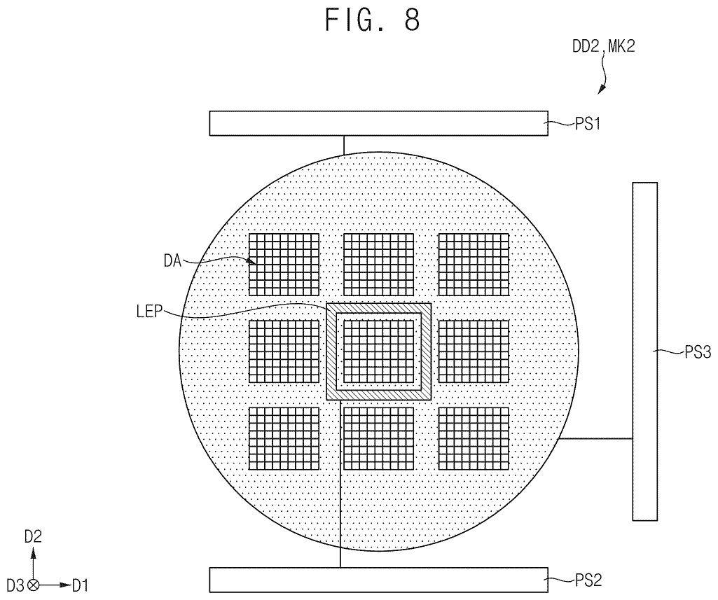

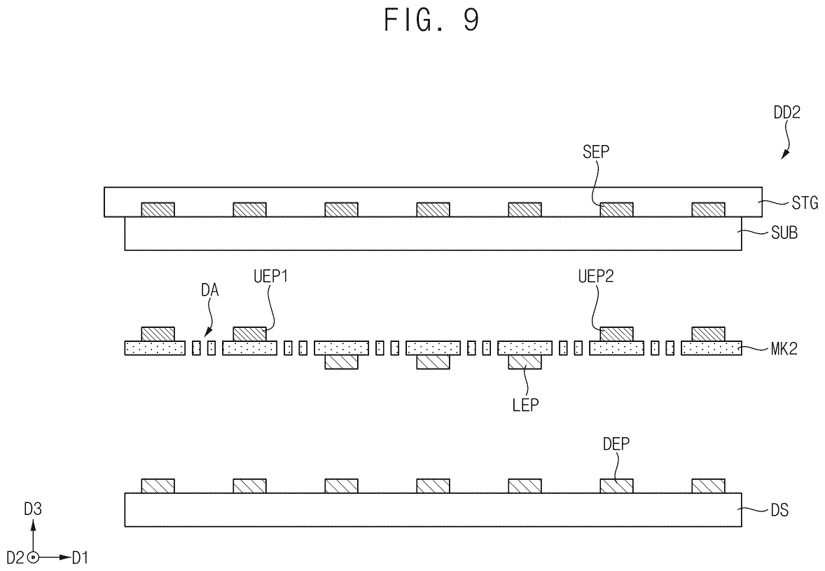

FIG. 7 is a plan view illustrating a mask included in a deposition apparatus according to an embodiment of the disclosure. FIG. 8 is a rear view illustrating the mask of FIG. 7. FIG. 9 is a schematic diagram illustrating the deposition apparatus of FIG. 7.

Referring to FIGS. 7, 8, and 9, a deposition apparatus DD2 according to an embodiment of the disclosure may include a deposition source DS, a deposition source electrode pattern DEP, a mask MK2, a stage STG, and a stage electrode pattern SEP. The mask MK2 may include a support member, a pattern member, a first upper electrode pattern UEP1, a second upper electrode pattern UEP2, and a lower electrode pattern LEP. The deposition apparatus DD2 may deposit a deposition material on the deposition target substrate SUB.

In an embodiment, the deposition apparatus DD2 of FIGS. 7, 8, and 9 and the deposition device DD1 of FIGS. 1, 2, and 3 may be substantially the same, except for the mask MK2.

As shown in FIG. 7, the mask MK2 may include the first upper electrode pattern UEP1 and the second upper electrode pattern UEP2.

In an embodiment, the first upper electrode pattern UEP1 may be disposed on the pattern member 200 (or the support member 100). In another embodiment, the first upper electrode pattern UEP1 may be mounted inside the pattern member 200 (or the support member 100).

In an embodiment, the first upper electrode pattern UEP1 may be formed of an electrically conductive conductor. For example, the first upper electrode pattern UEP1 may be formed of a metal material. Accordingly, in case that a voltage is applied to the first upper electrode pattern UEP1, the first upper electrode pattern UEP1 may have a polarity.

In another embodiment, the first upper electrode pattern UEP1 may be formed of a magnetic material that conducts magnetism.

In an embodiment, the second upper electrode pattern UEP2 may be disposed on the pattern member 200 (or the support member 100). In another embodiment, the second upper electrode pattern UEP2 may be mounted inside the pattern member 200 (or the support member 100).

In an embodiment, the second upper electrode pattern UEP2 may be formed of an electrical conductor. For example, the second upper electrode pattern UEP2 may be formed of a metal material. Accordingly, in case that a voltage is applied to the second upper electrode pattern UEP2, the second upper electrode pattern UEP2 may have a polarity.

In another embodiment, the second upper electrode pattern UEP2 may be formed of a magnetic material that conducts magnetism.

In an embodiment, the second upper electrode pattern UEP2 may be spaced apart from the first upper electrode pattern UEP1. For example, the second upper electrode pattern UEP2 may be electrically insulated from the first upper electrode pattern UEP1.

For example, the first upper electrode pattern UEP1 and the second upper electrode pattern UEP2 may be disposed adjacent to a circumference of the mask MK2. The shape of the second upper electrode pattern UEP2 may be symmetrical to the shape of the first upper electrode pattern UEP1.

In an embodiment, the first upper electrode pattern UEP1 may be electrically connected to a first power source PS1, and the second upper electrode pattern UEP2 may be electrically connected to a third power source PS3.

The polarity and magnitude of the voltage applied to the first upper electrode pattern UEP1 may be appropriately set as needed. The polarity and magnitude of the voltage applied to the second upper electrode pattern UEP2 may be appropriately set as needed.

In an embodiment, the polarity of the voltage applied to the first upper electrode pattern UEP1 and the polarity of the voltage applied to the second upper electrode pattern UEP2 may be the same. The magnitude of the voltage applied to the first upper electrode pattern UEP1 and the magnitude of the voltage applied to the second upper electrode pattern UEP2 may be different from each other.

As shown in FIG. 8, the mask MK2 may include the lower electrode pattern LEP. In an embodiment, the lower electrode pattern LEP may be disposed under the pattern member 200 (or the support member 100). In another embodiment, the lower electrode pattern (LEP) may be mounted inside the pattern member 200 (or the support member 100).

For example, the lower electrode pattern LEP may be disposed at the center of the mask MK2 in a plan view.

In an embodiment, the lower electrode pattern LEP may be formed of an electrically conductive conductor. For example, the lower electrode pattern LEP may be formed of a metal material. Accordingly, in case that a voltage is applied to the lower electrode pattern LEP, the lower electrode pattern LEP may have a polarity.

In another embodiment, the lower electrode pattern LEP may be formed of a magnetic material that conducts magnetism.

In an embodiment, the lower electrode pattern LEP may be electrically connected to a second power source PS2. The polarity and magnitude of the voltage applied to the lower electrode pattern LEP may be appropriately set as needed.

As shown in FIG. 9, a voltage having a same positive polarity (+) may be applied to the first upper electrode pattern UEP1, the second upper electrode pattern UEP2, and the stage electrode pattern SEP. Accordingly, a repulsive force may occur between the first upper electrode pattern UEP1 and the stage electrode pattern SEP, and a repulsive force may occur between the second upper electrode pattern UEP2 and the stage electrode pattern SEP. Accordingly, collision between the deposition target substrate SUB and the mask MK2 may be prevented.

A voltage having a same negative polarity (−) may be applied to the lower electrode pattern LEP and the deposition source electrode pattern DEP. Accordingly, a repulsive force may occur between the lower electrode pattern LEP and the deposition source electrode pattern DEP. Accordingly, the mask MK2 may not sag downward.

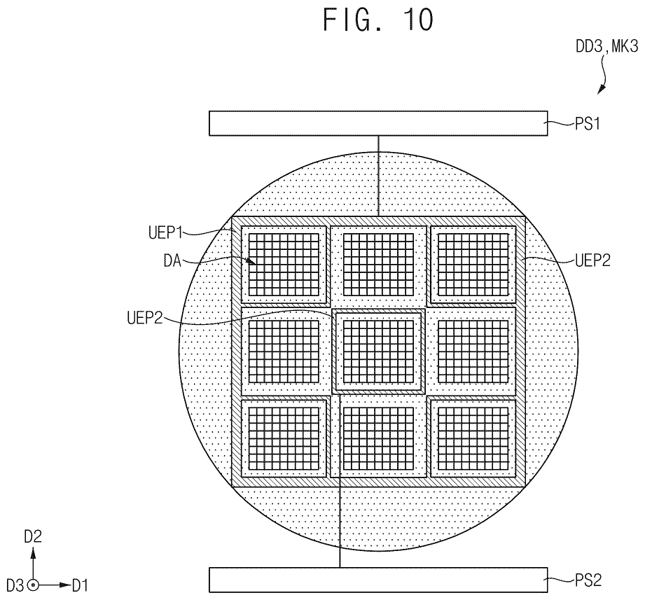

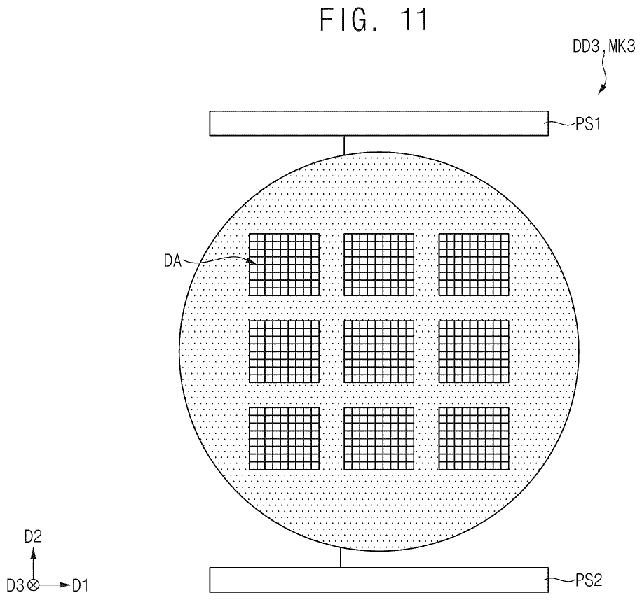

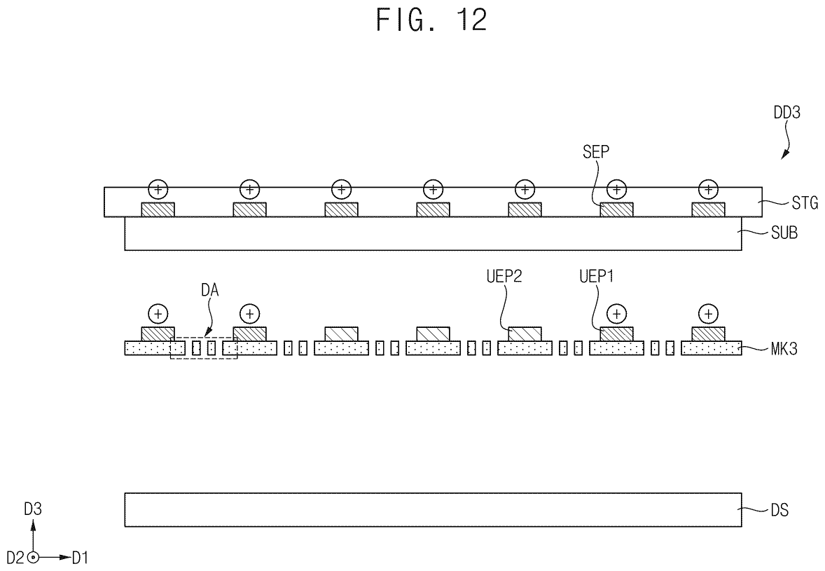

FIG. 10 is a plan view illustrating a mask included in a deposition apparatus according to an embodiment of the disclosure. FIG. 11 is a rear view illustrating the mask of FIG. 10. FIGS. 12, 13, and 14 are schematic diagrams illustrating a deposition method using the deposition apparatus of FIG. 10.

Referring to FIGS. 10 and 11, a deposition apparatus DD3 according to an embodiment of the disclosure may include a deposition source DS, a mask MK3, a stage STG, and a stage electrode pattern SEP. The mask MK3 may include a support member, a pattern member, a first upper electrode pattern UEP1, and a second upper electrode pattern UEP2. The deposition apparatus DD3 may deposit a deposition material on the deposition target substrate SUB.

In an embodiment, the deposition apparatus DD3 of FIGS. 10 and 11 and the deposition device DD1 of FIGS. 1, 2, and 3 may be substantially the same, except for the mask MK3.

As shown in FIG. 10, the mask MK3 may include the first upper electrode pattern UEP1 and the second upper electrode pattern UEP2.

In an embodiment, the first upper electrode pattern UEP1 may be disposed on the pattern member 200 (or the support member 100). In another embodiment, the first upper electrode pattern UEP1 may be mounted inside the pattern member 200 (or the support member 100).

In an embodiment, the first upper electrode pattern UEP1 may be formed of an electrically conductive conductor. For example, the first upper electrode pattern UEP1 may be formed of a metal material. Accordingly, in case that a voltage is applied to the first upper electrode pattern UEP1, the first upper electrode pattern UEP1 may have a polarity.

In another embodiment, the first upper electrode pattern UEP1 may be formed of a magnetic material that conducts magnetism.

In an embodiment, the second upper electrode pattern UEP2 may be disposed on the pattern member 200 (or the support member 100). In another embodiment, the second upper electrode pattern UEP2 may be mounted inside the pattern member 200 (or the support member 100).

In an embodiment, the second upper electrode pattern UEP2 may be formed of an electrical conductor. For example, the second upper electrode pattern UEP2 may be formed of a metal material. Accordingly, in case that a voltage is applied to the second upper electrode pattern UEP2, the second upper electrode pattern UEP2 may have a polarity.

In another embodiment, the second upper electrode pattern UEP2 may be formed of a magnetic material that conducts magnetism.

In an embodiment, the second upper electrode pattern UEP2 may be spaced apart from the first upper electrode pattern UEP1. For example, the second upper electrode pattern UEP2 may be electrically insulated from the first upper electrode pattern UEP1.

For example, the first upper electrode pattern UEP1 may be disposed adjacent to a circumference of the mask MK3, and the second upper electrode pattern UEP2 may be disposed at the center of the mask MK3 in a plan view. The first upper electrode pattern UEP1 may surround the second upper electrode pattern UEP2 in a plan view.

In an embodiment, the first upper electrode pattern UEP1 may be electrically connected to a first power source PS1, and the second upper electrode pattern UEP2 may be electrically connected to a second power source PS2.

The polarity and magnitude of the voltage applied to the first upper electrode pattern UEP1 may be appropriately set as needed. The polarity and magnitude of the voltage applied to the second upper electrode pattern UEP2 may be appropriately set as needed.

In an embodiment, the polarity of the voltage applied to the first upper electrode pattern UEP1 and the polarity of the voltage applied to the second upper electrode pattern UEP2 may be different from each other.

As shown in FIG. 11, a lower electrode pattern may not be formed on the mask MK3.

Referring to FIG. 12, the deposition target substrate SUB may be fixed to the stage STG, and the mask MK3 may be loaded.

While the mask MK3 is being loaded, a voltage may be applied to the first upper electrode pattern UEP1 included in the mask MK3. For example, a voltage having a positive polarity (+) may be applied to the first upper electrode pattern UEP1.

While the mask MK3 is loaded, a voltage may be applied to the stage electrode pattern SEP. For example, while a voltage with a positive polarity (+) is applied to the first upper electrode pattern UEP1, a voltage with a positive polarity (+) may be applied to the stage electrode pattern SEP.

As a voltage having a same positive polarity (+) is applied to the first upper electrode pattern UEP1 and the stage electrode pattern SEP, a repulsive force may occur between the first upper electrode pattern UEP1 and the stage electrode pattern SEP. Accordingly, collision between the deposition target substrate SUB and the mask MK3 may be prevented.

As the magnitude of the voltage applied to the first upper electrode pattern UEP1 and the stage electrode pattern SEP are adjusted, the gap between the mask MK3 and the deposition target substrate SUB may be adjusted.

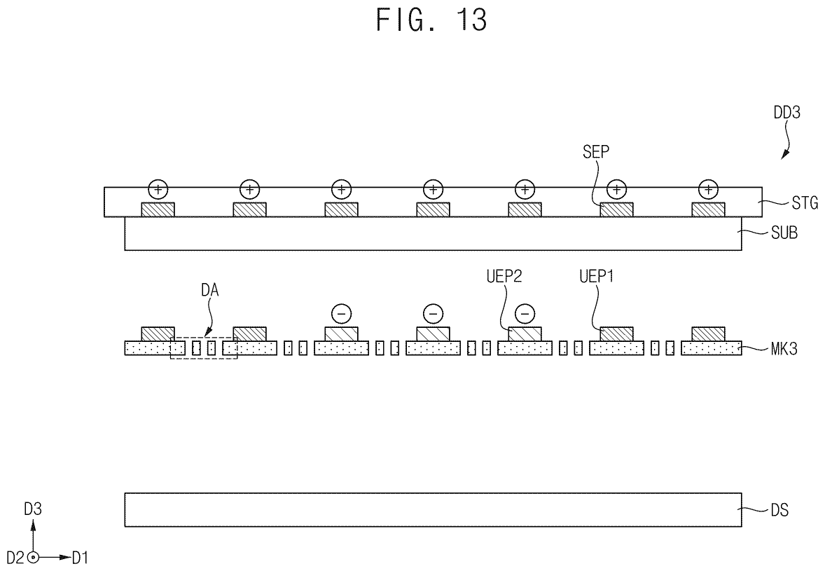

Referring to FIG. 13, the deposition process may be proceeded.

While the deposition process is in progress, a voltage may be applied to the second upper electrode pattern UEP2 included in the mask MK3. For example, a voltage having a negative polarity (−) may be applied to the second upper electrode pattern UEP2. In other words, the polarity of the voltage applied to the second upper electrode pattern UEP2 and the polarity of the voltage applied to the first upper electrode pattern UEP1 may be different from each other.

While the deposition process is in progress, a voltage may be applied to the stage electrode pattern SEP. For example, while a voltage with a negative polarity (−) is applied to the second upper electrode pattern UEP2, a voltage with a positive (+) polarity may be applied to the stage electrode pattern SEP.

As voltages having different polarities are applied to the second upper electrode pattern UEP2 and the stage electrode pattern SEP, an attractive force may occur between the second upper electrode pattern UEP2 and the stage electrode pattern SEP. Accordingly, the mask MK3 may not sag downward.

As the magnitude of the voltage applied to the second upper electrode pattern UEP2 and the stage electrode pattern SEP are adjusted, the gap between the mask MK3 and the deposition source DS may be adjusted.

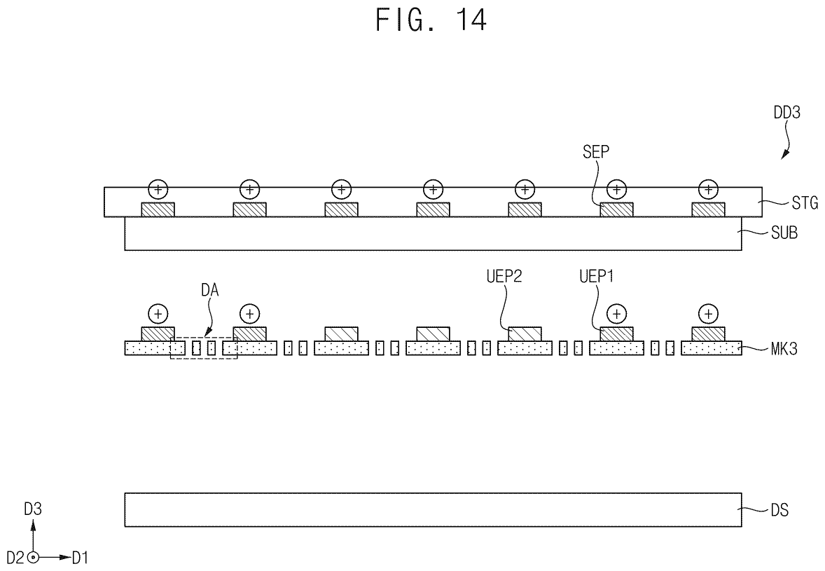

Referring to FIG. 14, the mask MK3 may be unloaded.

While the mask MK3 is unloaded, a voltage having a positive polarity (+) may be applied to the first upper electrode pattern UEP1. While a voltage with a positive polarity (+) is applied to the first upper electrode pattern UEP1, a voltage with a positive polarity (+) may be applied to the stage electrode pattern SEP.

As a voltage having a same positive polarity (+) is applied to the first upper electrode pattern UEP1 and the stage electrode pattern SEP, a repulsive force may occur between the first upper electrode pattern UEP1 and the stage electrode pattern SEP. Accordingly, collision between the deposition target substrate SUB and the mask MK1 may be prevented.

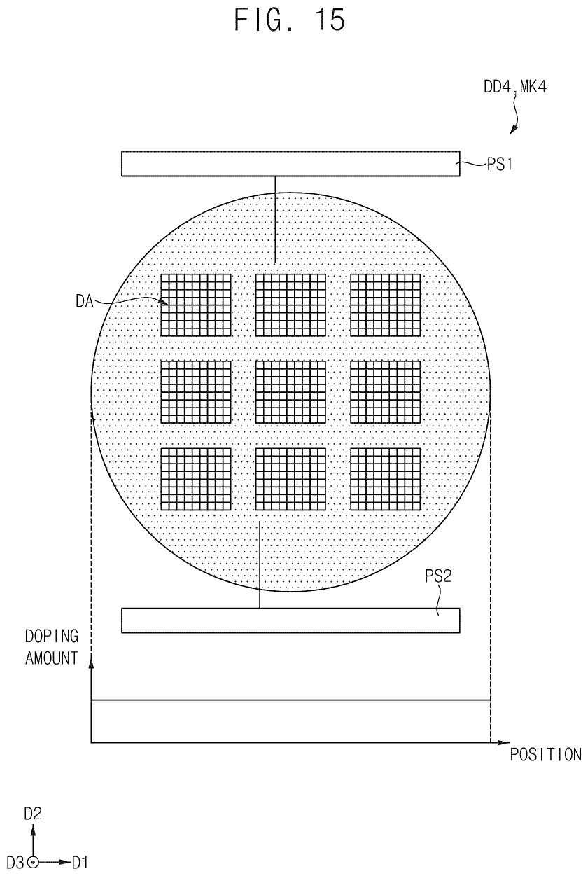

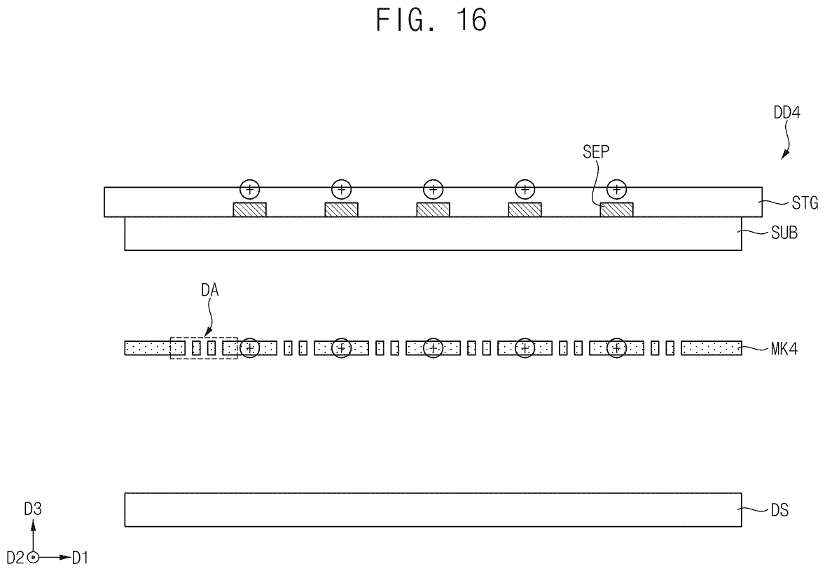

FIG. 15 is a plan view illustrating a mask included in a deposition apparatus according to an embodiment of the disclosure. FIGS. 16, 17, and 18 are schematic diagrams illustrating a deposition method using the deposition apparatus of FIG. 15.

Referring to FIG. 15, a deposition apparatus DD4 according to an embodiment of the disclosure may include a deposition source DS, a mask MK4, a stage STG, and a stage electrode pattern SEP. The deposition apparatus DD4 may deposit a deposition material on the deposition target substrate SUB.

In an embodiment, the deposition apparatus DD4 of FIG. 15 and the deposition device DD1 of FIGS. 1, 2, and 3 may be substantially the same, except for the mask MK4.

In an embodiment, the mask MK4 may be doped with an electrode material. In an embodiment, the electrode material may be an electrically conductive material (e.g., a metal material). Accordingly, in case that a voltage is applied to the electrode material, the mask MK4 may have a polarity.

In an embodiment, as shown in FIG. 15, the doping amount with which the electrode material is doped may be substantially uniform. For example, the doping amount of the electrode material doped at a circumference of the mask MK4 and the doping amount of the electrode material doped at the center of the mask MK4 may be substantially the same.

In another embodiment, the inside of the mask MK4 may be doped with a magnetic material that conducts magnetism.

Referring to FIG. 16, the deposition target substrate SUB may be fixed to the stage STG, and the mask MK4 may be loaded.

While the mask MK4 is loaded, a voltage may be applied to the electrode material doped in the mask MK4. For example, a voltage having a positive polarity (+) may be applied to the mask MK4. Since the doping amount of the electrode material is substantially uniform, the magnitude of the voltage applied to the mask MK4 may be substantially uniform.

While the mask MK4 is loaded, a voltage may be applied to the stage electrode pattern SEP. For example, while a voltage with a positive polarity (+) is applied to the mask MK4, a voltage with a positive polarity (+) may be applied to the stage electrode pattern SEP.

As a voltage having a same positive polarity (+) is applied to the mask MK4 and the stage electrode pattern SEP, a repulsive force may occur between the mask MK4 and the stage electrode pattern SEP. Accordingly, collision between the deposition target substrate SUB and the mask MK4 may be prevented.

As the magnitude of the voltage applied to the mask MK4 and the stage electrode pattern SEP are adjusted, the gap between the mask MK4 and the deposition target substrate SUB may be adjusted.

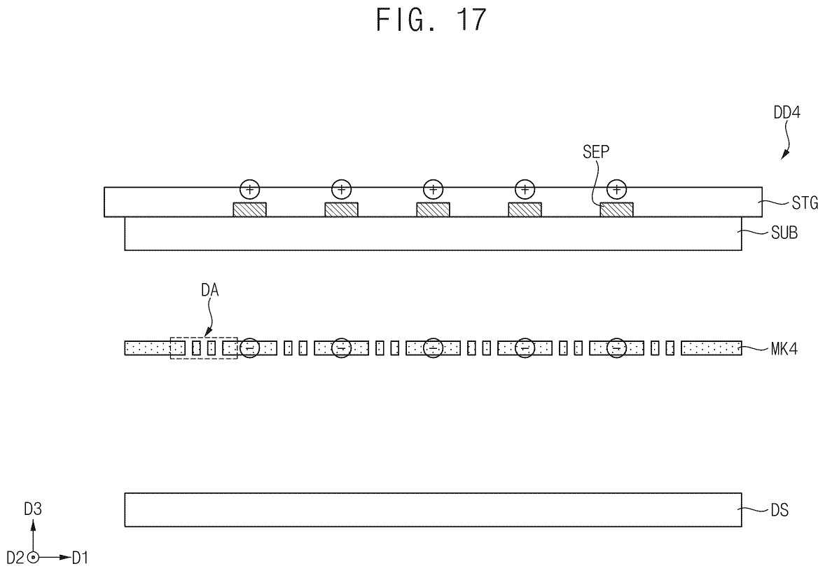

Referring to FIG. 17, the deposition process may be proceeded.

While the deposition process is in progress, a voltage may be applied to the electrode material included in the mask MK4. For example, a voltage having a negative polarity (−) may be applied to the mask MK4.

While the deposition process is in progress, a voltage may be applied to the stage electrode pattern SEP. For example, while a voltage with a negative polarity (−) is applied to the mask MK4, a voltage with a positive (+) polarity may be applied to the stage electrode pattern SEP.

As voltages having different polarities are applied to the mask MK4 and the stage electrode pattern SEP, an attractive force may occur between the mask MK4 and the stage electrode pattern SEP. Accordingly, the mask MK4 may not sag downward.

As the magnitude of the voltage applied to the mask MK4 and the stage electrode pattern SEP are adjusted, the gap between the mask MK4 and the deposition source DS may be adjusted.

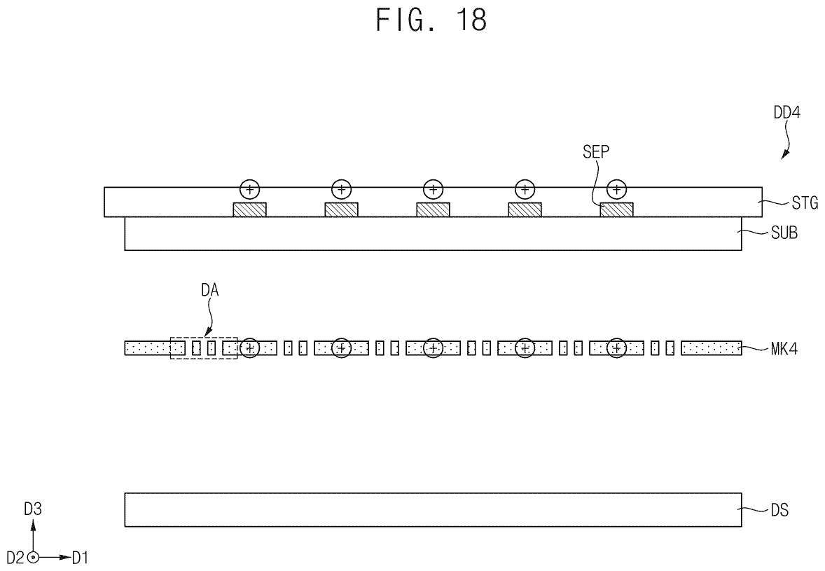

Referring to FIG. 18, the mask MK4 may be unloaded.

While the mask MK4 is unloaded, a voltage having a positive polarity (+) may be applied to the electrode material doped into the mask MK4. While a voltage having a positive polarity (+) is applied to the mask MK4, a voltage having a positive polarity (+) may be applied to the stage electrode pattern SEP.

As a voltage having a same positive polarity (+) is applied to the mask MK4 and the stage electrode pattern SEP, a repulsive force may occur between the mask MK4 and the stage electrode pattern SEP. Accordingly, collision between the deposition target substrate SUB and the mask MK4 may be prevented.

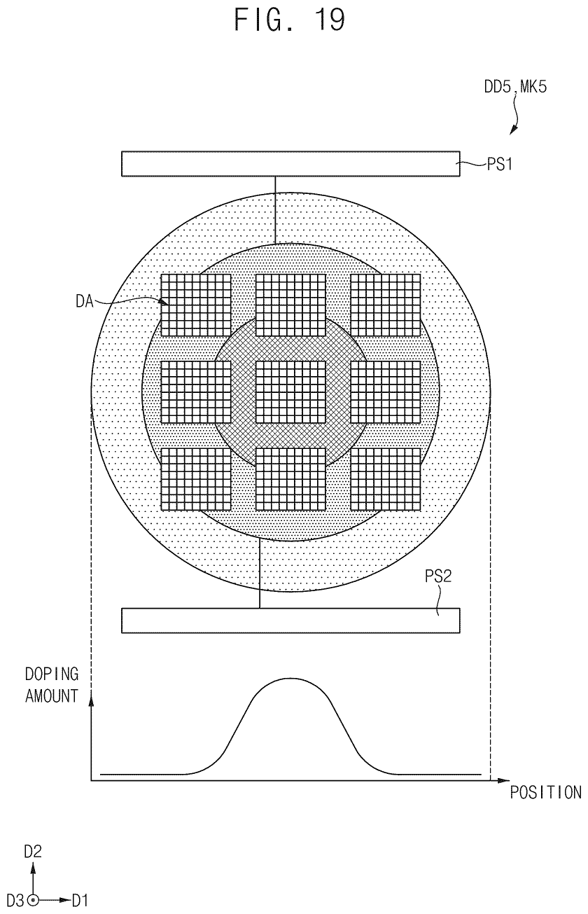

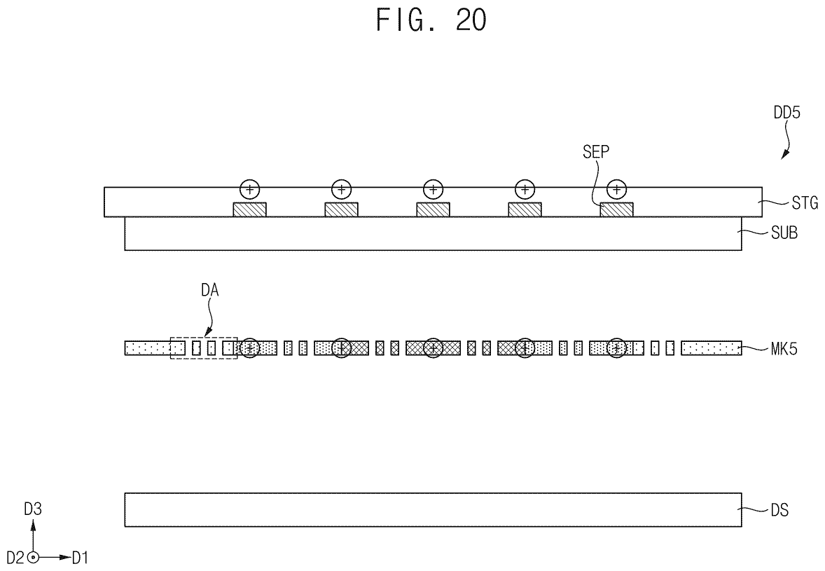

FIG. 19 is a plan view illustrating a mask included in a deposition apparatus according to an embodiment of the disclosure. FIGS. 20, 21, and 22 are schematic diagrams illustrating a deposition method using the deposition apparatus of FIG. 19.

Referring to FIG. 19, a deposition apparatus DD5 according to an embodiment of the disclosure may include a deposition source DS, a mask MK5, a stage STG, and a stage electrode pattern SEP. The deposition apparatus DD5 may deposit a deposition material on the deposition target substrate SUB.

In an embodiment, the deposition apparatus DD5 of FIG. 19 and the deposition apparatus DD1 of FIGS. 1, 2, and 3 may be substantially the same, except for the mask MK5.

In an embodiment, the mask MK5 may be doped with an electrode material. In an embodiment, the electrode material may be an electrically conductive material (e.g., a metal material). Accordingly, in case that a voltage is applied to the electrode material, the mask MK5 may have a polarity.

In an embodiment, as shown in FIG. 19, the amount of doping with which the electrode material is doped may be substantially non-uniform. For example, the doping amount of the electrode material doped at a circumference of the mask MK5 may be smaller than the doping amount of the electrode material doped at the center of the mask MK5.

In another embodiment, the mask MK5 may be doped with a magnetic material that conducts magnetism.

Referring to FIG. 20, the deposition target substrate SUB may be fixed to the stage STG, and the mask MK5 may be loaded.

While the mask MK5 is loaded, a voltage may be applied to the electrode material doped in the mask MK5. For example, a voltage having a positive polarity (+) may be applied to the mask MK5. Since the doping amount of the electrode material doped at the center of the mask MK5 is relatively large, the magnitude of the voltage applied to the center of the mask MK5 may be relatively large.

While the mask MK5 is loaded, a voltage may be applied to the stage electrode pattern SEP. For example, while a voltage having a positive polarity (+) is applied to the mask MK5, a voltage having a positive polarity (+) may be applied to the stage electrode pattern SEP.

As a voltage having a same positive polarity (+) is applied to the mask MK5 and the stage electrode pattern SEP, a repulsive force may occur between the mask MK5 and the stage electrode pattern SEP. Accordingly, collision between the deposition target substrate SUB and the mask MK5 may be prevented.

As the magnitude of the voltage applied to the mask MK5 and the stage electrode pattern SEP are adjusted, the gap between the mask MK5 and the deposition target substrate SUB may be adjusted.

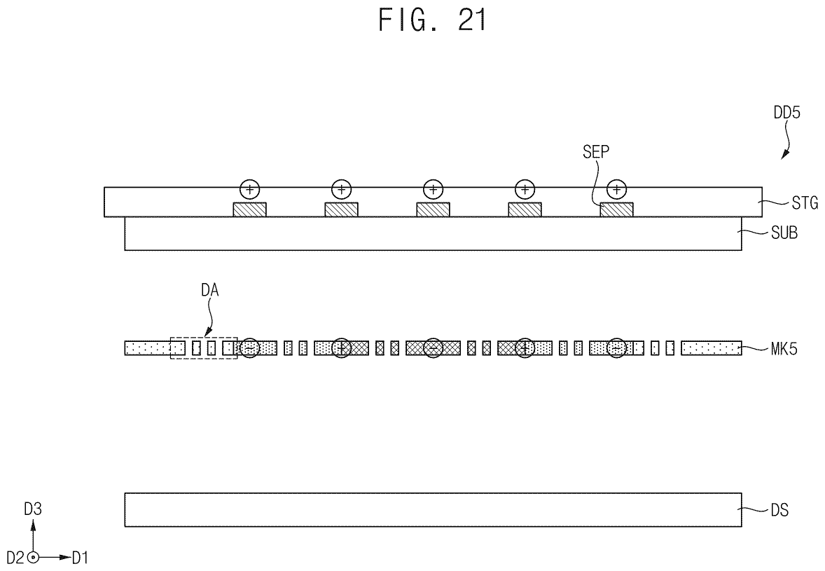

Referring to FIG. 21, the deposition process may be proceeded.

While the deposition process is in progress, a voltage may be applied to the electrode material included in the mask MK5. For example, a voltage having a negative polarity (−) may be applied to the mask MK5.

While the deposition process is in progress, a voltage may be applied to the stage electrode pattern SEP. For example, while a voltage with a negative polarity (−) is applied to the mask MK5, a voltage with a positive (+) polarity may be applied to the stage electrode pattern SEP.

As voltages having different polarities are applied to the mask MK5 and the stage electrode pattern SEP, an attractive force may occur between the mask MK5 and the stage electrode pattern SEP. Accordingly, the mask MK5 may not sag downward.

As the magnitude of the voltage applied to the mask MK5 and the stage electrode pattern SEP are adjusted, the gap between the mask MK5 and the deposition source DS may be adjusted.

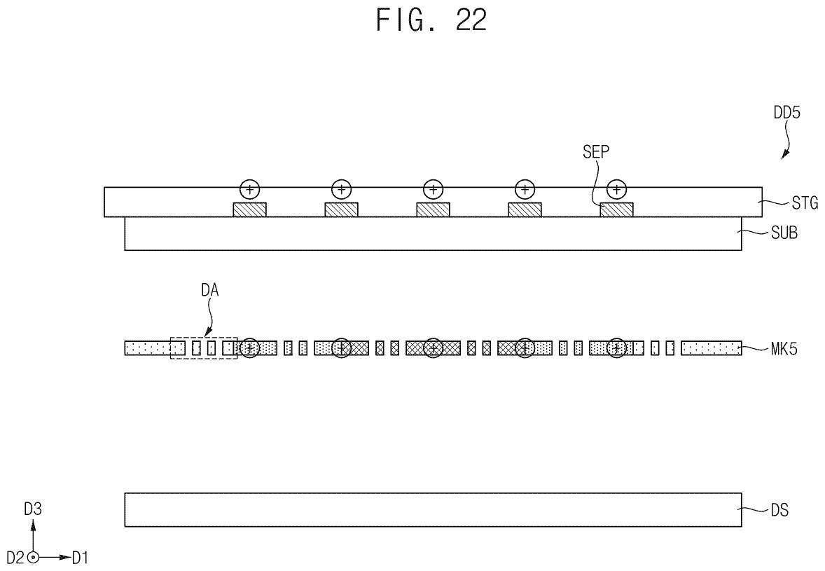

Referring to FIG. 22, the mask MK5 may be unloaded.

While the mask MK5 is unloaded, a voltage having a positive polarity (+) may be applied to the electrode material doped into the mask MK5. While a voltage having a positive polarity (+) is applied to the mask MK5, a voltage having a positive polarity (+) may be applied to the stage electrode pattern SEP.

As a voltage having a same positive polarity (+) is applied to the mask MK5 and the stage electrode pattern SEP, a repulsive force may occur between the mask MK5 and the stage electrode pattern SEP. Accordingly, collision between the deposition target substrate SUB and the mask MK5 may be prevented.

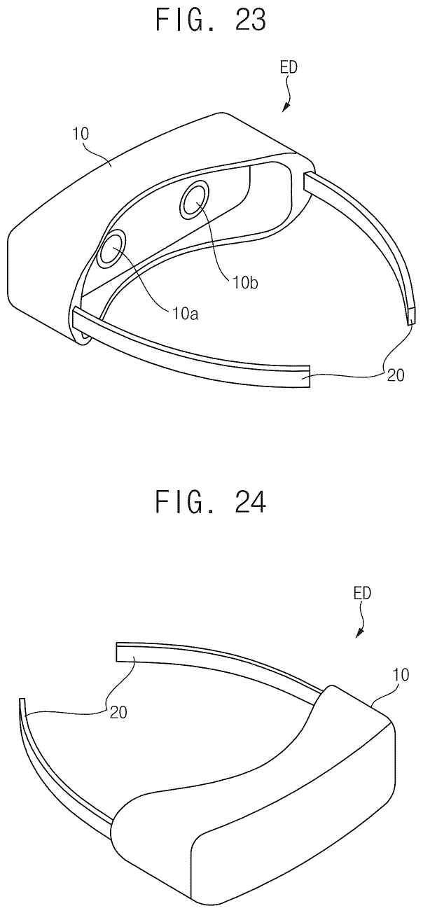

FIGS. 23 and 24 are perspective views illustrating an electronic device according to an embodiment of the disclosure.

Referring to FIGS. 23 and 24, the electronic device ED according to an embodiment of the disclosure may include a display module housing 10, a first eyepiece 10a, a second eyepiece 10b, and an eyeglass frame legs 20. For example, the electronic device ED may be implemented as a head mounted display. Therefore, hereinafter, the electronic device ED will be described by taking the head-mounted display as an embodiment.

The display module housing 10 may include a display module and an optical member (not illustrated). The display module may display images. The optical member may provide images displayed on the display module to the first and second eyepieces 10a and 10b. For example, the display module may be manufactured from the deposition target substrate SUB described with reference to FIGS. 1 to 22.

The first and second eyepieces 10a and 10b may be disposed on a side of the display module housing 10. For example, the first and second eyepieces 10a and 10b may be disposed on the rear surface of the display module housing 10. For example, the first eyepiece 10a may be a left eye lens where the user's left eye is located, and the second eyepiece 10b may be a right eye lens where the user's right eye is located. The user may view the image displayed by the display module of the display module housing 10 through the first and second eyepieces 10a and 10b.

The electronic device ED may provide the image displayed on the display module of the display module housing 10 to the user through the first and second eyepieces 10a and 10b. As a result, the electronic device ED may provide a virtual image displayed by the display module of the display module housing 10 to the user. In other words, the electronic device ED may implement virtual reality (VR).

The eyeglass frame legs 20 may be configured so that the user may readily put the electronic device ED on or take the electronic device ED off. However, the configuration of the disclosure is not limited to this, and the electronic device ED may include a head-mounted band that can be mounted on the head instead of the eyeglass frame legs 20.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A deposition apparatus comprising:
a deposition source which accommodates a deposition material;
a mask through which the deposition material passes, disposed on the deposition source, and including a first upper electrode pattern to which a first voltage is applied;
a stage disposed on the mask and on which a deposition target substrate on which the deposition material is deposited is fixed; and
a stage electrode pattern disposed on the mask and to which a second voltage is applied,
wherein a polarity of the first voltage and a polarity of the second voltage are same.

2. The deposition apparatus of claim 1, wherein a repulsive force occurs between the stage electrode pattern and the first upper electrode pattern.

3. The deposition apparatus of claim 1, wherein the mask further includes:
a second upper electrode pattern to which a third is applied, wherein
a polarity of the third voltage and the polarity of the first voltage are same,
a magnitude of the third voltage and a magnitude of the first voltage are different from each other, and
the second upper electrode pattern and the first upper electrode pattern are spaced apart from each other.

4. The deposition apparatus of claim 1, wherein the mask further includes:
a second upper electrode pattern to which a third voltage is applied, wherein
a polarity of the third voltage and the polarity of the first voltage are different from each other.

5. The deposition apparatus of claim 4, wherein
the first upper electrode pattern is disposed adjacent to a circumference of the mask, and
the second upper electrode pattern is disposed at a center of the mask.

6. The deposition apparatus of claim 1, wherein the mask further includes:
a lower electrode pattern to which a third voltage is applied, wherein
a polarity of the third voltage and the polarity of the first voltage are different from each other.

7. The deposition apparatus of claim 6, further comprising:
a deposition source electrode pattern disposed on the deposition source and to which a fourth voltage is applied, wherein
the polarity of the third voltage and a polarity of the fourth voltage are same.

8. The deposition apparatus of claim 6, wherein
the first upper electrode pattern is disposed adjacent to a circumference of the mask, and
the lower electrode pattern is disposed at a center of the mask.

9. The deposition apparatus of claim 1, wherein
deposition areas in which a plurality of openings are formed are defined in the mask, and
the first upper electrode pattern is disposed between the deposition areas.

10. The deposition apparatus of claim 1, wherein the mask includes silicon.

11. A deposition apparatus comprising:
a deposition source which accommodates a deposition material;
a mask through which the deposition material passes, disposed on the deposition source, and doped with an electrode material to which a first voltage is applied;
a stage disposed on the mask and on which a deposition target substrate on which the deposition material is deposited is fixed; and
a stage electrode pattern disposed on the mask and to which a second voltage is applied.

12. The deposition apparatus of claim 11, wherein a polarity of the first voltage and a polarity of the second voltage are same.

13. The deposition apparatus of claim 11, wherein a polarity of the first voltage and a polarity of the second voltage are different from each other.

14. The deposition apparatus of claim 11, wherein a doping amount of the electrode material at a circumference of the mask and a doping amount of the electrode material doped at a center of the mask are substantially same.

15. The deposition apparatus of claim 11, wherein a doping amount of the electrode material at a circumference of the mask is smaller than a doping amount of the electrode material doped at a center of the mask.

16. A deposition method comprising:
applying a first voltage to an upper electrode pattern included in a mask, while the mask is being loaded;
applying a second voltage to a stage electrode pattern disposed on the mask, while the mask is being loaded;
applying a third voltage to a lower electrode pattern included in the mask, while a deposition process is in progress;
applying a fourth voltage to a deposition source electrode pattern disposed under the mask, while the deposition process is in progress;
applying a fifth voltage to the upper electrode pattern, while the mask is being unloaded; and
applying a sixth voltage to the stage electrode pattern, while the mask is being unloaded,
wherein a polarity of the first voltage and a polarity of the second voltage are same.

17. The deposition method of claim 16, wherein a polarity of the third voltage and a polarity of the fourth voltage are same.

18. The deposition method of claim 16, wherein a polarity of the fifth voltage and a polarity of the sixth voltage are same.

19. The deposition method of claim 16, wherein
a polarity of the first voltage and a polarity of the third voltage are different from each other, and
a polarity of the fifth voltage and the polarity of the third voltage are different from each other.
